(19) United States
(12) Patent Application Publication
(10) Pub. No.: US 2010/0039762 A1
(43) Pub. Date: Feb. 18, 2010

(54) Powered wall mount media display and data transfer system

(76) Inventor: Eric Watson, San Diego, CA (US)

Correspondence Address: Christina Ezell, 5133 Harding Rd. STE B-10 PMB 200, Nashville, TN, 37205, US

(21) Appl. No.: 12/228,913

(22) Filed: Aug. 18, 2008

(51) Int. Cl. H05K 7/00

(52) U.S. Cl. 361/679.21

(57) ABSTRACT

A method and device for a powered wall-mount illuminated media display and data transfer system is disclosed. The powered wall-mounted illuminated media display and data transfer system has a decorative glass top held by a wall mounted bracket. The powered display and data transfer system has a powered section in the front hinged connected to the bracket at a pivot point The glass section extends across the horizontal plane of the system, and this allows the system to hold multiple media devices. The wall-mounting bracket will hold the weight of the glass and several handheld devices while allowing its powered section to pivot. The powered section powers and stores all power cables while allowing multiple data transfer cables to connect and send signals through connecting cables or other wireless signals. The powered section conceals all wires and has color-coded connecting points to provide ease of access to the user.

### CROSS REFERENCES TO RELATED APPLICATIONS

None.

### BACKGROUND

1. Field of the Invention

The present invention relates generally to a power data transfer shelf with enclosure, and more particularly, to a powered wall mount illuminated media display and data transfer system.

2. Description of the Related Art

Currently, powered shelves for media devices have speakers and surge protection capabilities and can hold as well as charge multiple devices. For example, Bedford Smart Collection, Linen Pin Board & Speakers™, and their Wall-Mounted Speaker Shelf™ mounts to the wall and receive power cables therein. The cables are threaded through openings or knockouts in the rear section to power media devices.

A common drawback of these approaches is none of the prior power shelves offer a data transfer feature combined with a surge protector that can send signals via cable or wireless to a computer or other electronic device. Moreover, none of the prior illuminated shelves have a pivoting feature that allows access to surge protector outlets and the data transfer sources. Further, none of the prior powered and illuminated shelves combines a shelf with a color-coded surge protector that helps to distinguish the location of wires with proper devices while concealing wires neatly in an enclosure. Finally, none of the prior shelves have removable covers that are self illuminating to display media devices.

Thus, there is still a need for an innovation that will recharge and transfer data between electronic devices while having a pivoting power section that allows easy connection and disconnection of cables. There is also a need for a color coding system where all wires are in one location in order to efficiently manage devices and cables. There also exists a need for a lighting system that would allow more light in the workspace and help the user find connectors in dimly lit rooms as well as display their electronic devices.

### SUMMARY OF THE INVENTION

The present invention meets this need by providing an innovation that is an all-in-one solution that would charge and transfer data on a single shelf via cables or wireless signals. The present invention allows the user to be able to look at a single device and be able to locate all the wires inside the enclosure. Furthermore, all of the electronics are protected from deadly surges from the power outlets. Finally, the present invention changes the physical appearance of the shelf allowing the changing of the cover and illumination methods of the shelf to match different owner's surroundings and personalities.

Accordingly, in an aspect of the present invention, a powered wall mount illuminated media display and data transfer system is disclosed. The powered wall-mounted illuminated media display and transfer system is comprised of a decorative glass top held by a wall mounted bracket and a powered section in the front Connected via a hinge apparatus to the bracket at a pivot point whereby the glass section extends across the horizontal plane of the system allows the system to hold multiple media devices. The wall mounting bracket holds the weight of the glass and the media components while allowing its powered section to pivot.

In another aspect of the present invention, the powered section conveniently powers and stores all power cables while allowing multiple data transfer cables to connect and send signals through connecting cables or other wireless signals. The powered section can be various shapes and sizes and have an illuminated cover to conceal all wires that are inside. The pivot point allows the powered section to pivot so that all color-coded connection points are easily accessible by the user.

In an exemplary embodiment of the present invention, the powered shelf charges multiple devices and transfers data while all of the devices are sitting on a horizontal glass platform. The powered shelf transfers data from the shelf via a cable or wireless signal to an electronic source without having to disconnect from one location to another. The powered shelf has a system where the owner can look at the device and instantly be able to pinpoint cables connected to the power section through a color-coded system. The powered shelf has a built in surge protector that protects all of the devices connected to the system. Finally, in the exemplary embodiment of the present invention, the powered shelf power section cover is customizable so that it can reflect the owner's surrounding and personality.

### BRIEF DESCRIPTION OF THE DRAWINGS

Having thus described the invention in general terms, reference will now be made to the accompanying drawings, which are not necessarily drawn to scale, and wherein:

FIG. 1 is a schematic section view of the present invention.

FIG. 2 is an enlarged right prospective view of the wall mounting bracket of the present invention.

FIG. 3A is an enlarged frontal view of the wall mounting bracket disconnected from the power and data transfer system of the present invention.

FIG. 3B is an enlarged top view of the media station detached from the case and mounting bracket of the present invention.

FIG. 3C is an enlarged bottom view of the media station detached from the case and mounting bracket of the present invention.

FIG. 3D is an enlarged section view of the case with the LED housing and the media station detached from the case of the present invention.

FIG. 4 is an enlarged right prospective view of the present invention in its open position.

FIG. 5 is a side view of the present invention in its closed position.

FIG. 6 is a right upwards view of the present invention in its closed position.

FIG. 7 is a perspective view of a half moon shape of the present invention in its closed position.

FIG. 8 is a frontal view of a half moon shape of the present invention in its closed position.

FIG. 9 is a top cutaway view of a half moon shape of the present invention in its closed position.

FIG. 10 is a right perspective view of a torch shape of the present invention.

FIG. 11 is a side view of a torch shape of the present invention.

FIG. 12 is a left and upward perspective view of a torch shape of the present invention

FIG. 13 is a rear upward perspective view of a torch shape of the present invention.

### DETAILED DESCRIPTION

The present invention now will be described more fully hereinafter with reference to the accompanying drawings, in which some, but not all embodiments of the invention are shown. Indeed, the invention may be embodied in many different forms and should not be construed as limited to the embodiments set forth herein; rather, these embodiments are provided so that this disclosure will satisfy applicable legal requirements. Like numerals refer to like elements throughout the views.

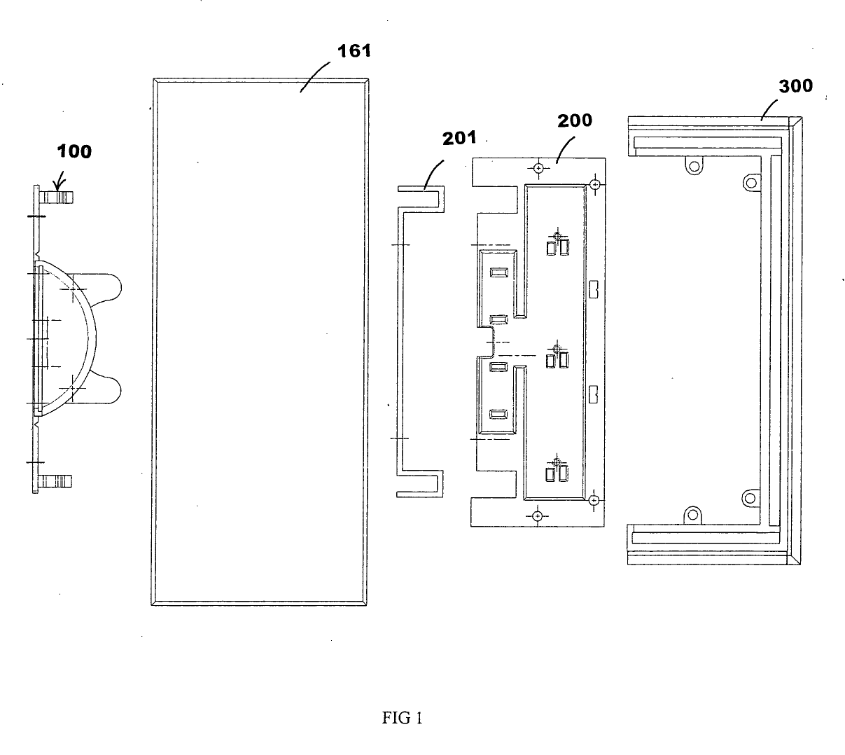

FIG. 1 illustrates a schematic sectional view of a power wall mount illuminated media display and data transfer system of the present invention which includes a glass shelf 161, a wall mounting foldable bracket 100, a pivoting and locking mechanism 201, a power and data transfer station 200, and an illuminated interchangeable case 300.

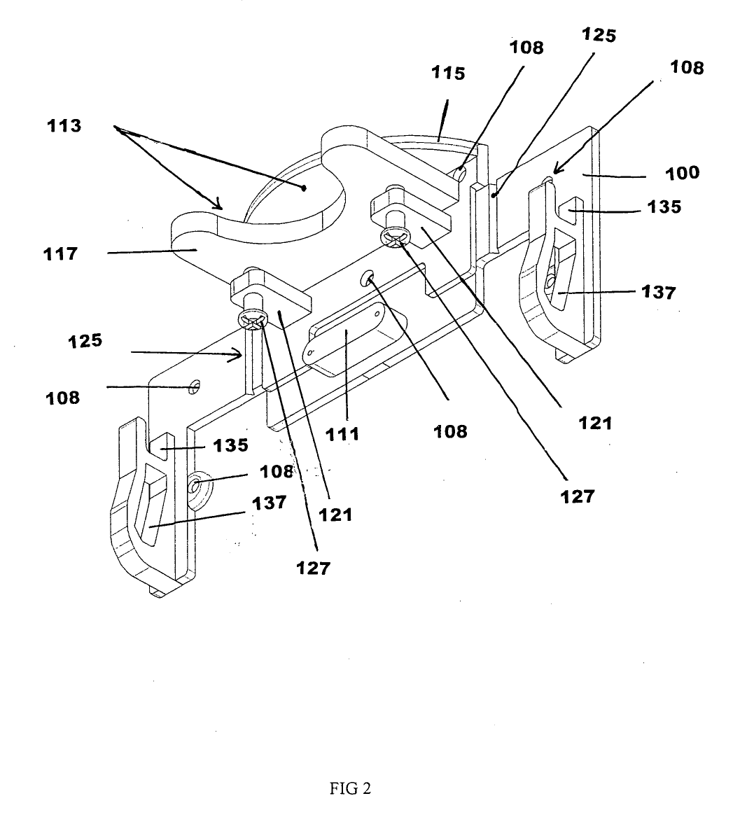

FIG. 2 illustrates an enlarged prospective view of the wall mounting foldable bracket 100 and its relationship with a pivoting and locking mechanism 201. The wall mounting foldable bracket 100 is adapted to and/or is formed with angled cuts 125, such as triangles or other shapes, causing the material under that area to be thinner and more flexible or foldable. Once unfolded at angled cuts 125, the wall mounting foldable bracket 100 can be placed on a wall and leveled using the leveling device 111. The leveling device 111 is mounted to the frame of the wall mounted foldable bracket 100 with screws or other suitable means of mounting. A plurality of mounting holes 108, are located strategically around the bracket to support the entire weight of the structure. The mounting holes can be various shapes, sizes, and quantity. Locking mechanisms 135 and pivot points 137 of the present invention secure the data transfer system to the wall bracket. Locking mechanisms 135 are comprised of magnets, hooks, pushbutton, tension mechanism, or other suitable structures that holds the glass shelf 161 in place while in the up position. The upper shelf holding bracket 115 holds the top of the glass shelf 161 (not shown in this figure) in place and is stationary and the lower shelf holding bracket 117 holds the bottom of the glass shelf 161 and can be adjusted up or down by the turn of screws 127. Screws 127 are held in place by screw guide 121, which is stationary and mounted to lower shelf holding bracket 117. Separator 113 allows a space for a solid chemical structure comprised of rubber, plastic, or other suitable material to prevent premature cracking or wear on the glass shelf 161. The wall mounting foldable bracket 100 is made out a range of materials or combination of materials that will allow said bracket 100 to pivot on an axis to allow easy access to a surge protected and data area.

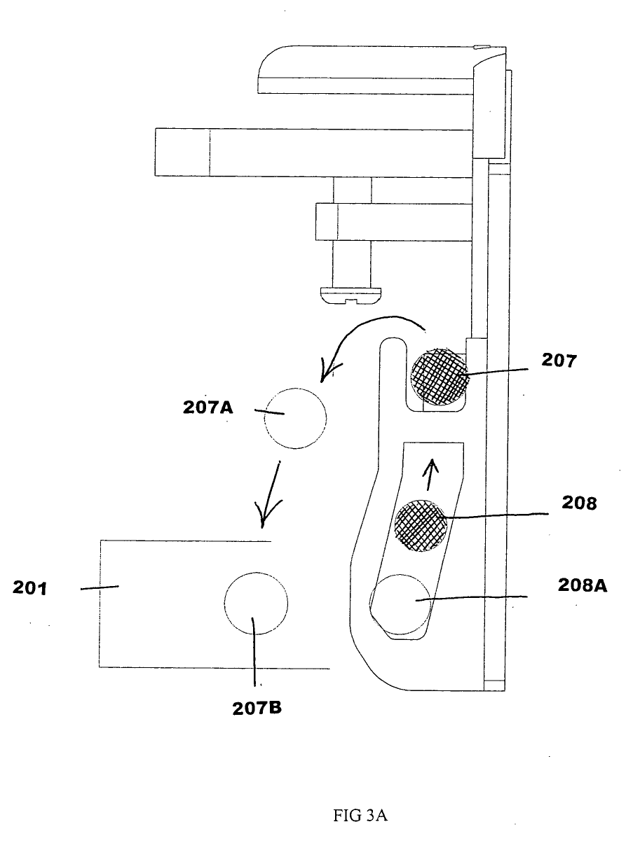

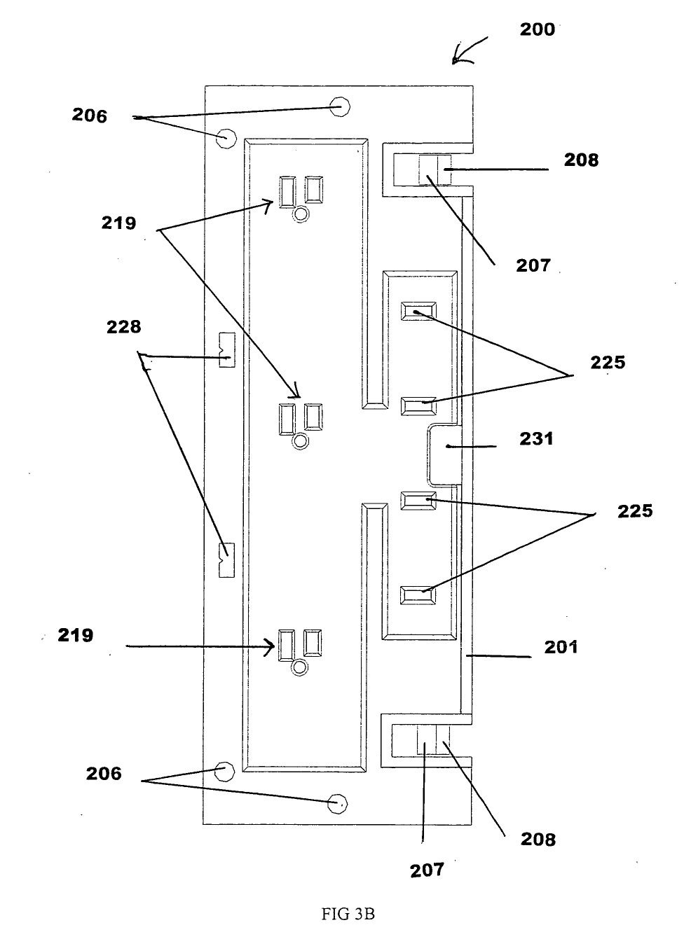

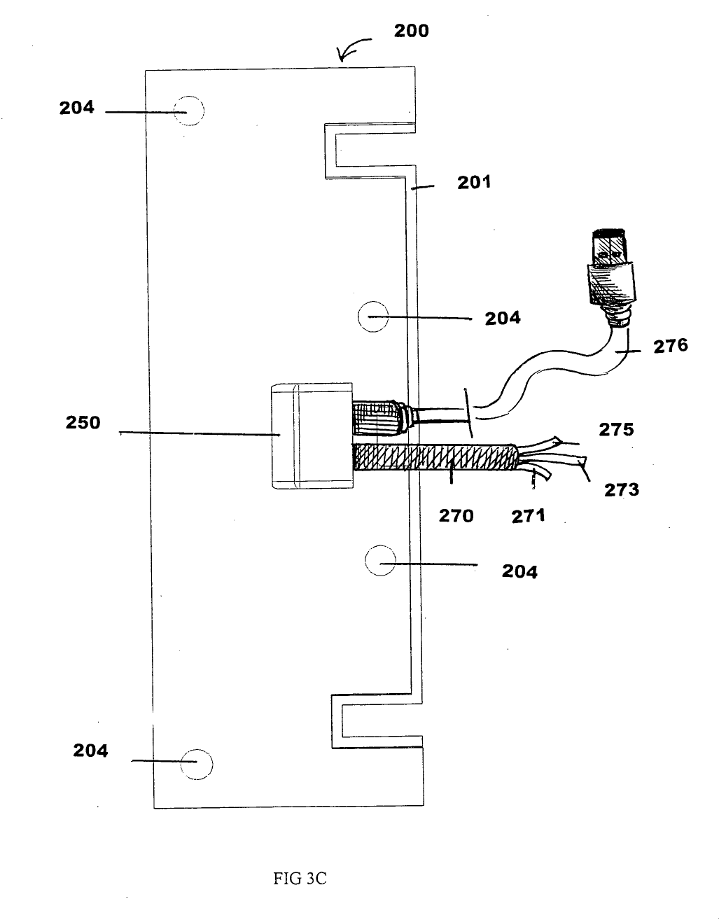

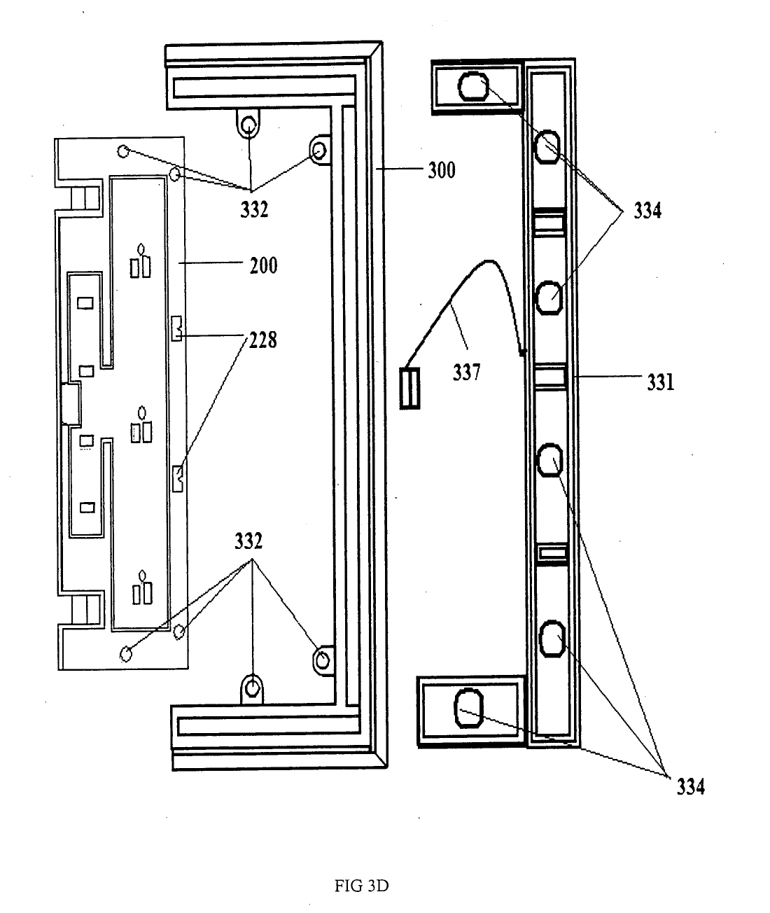

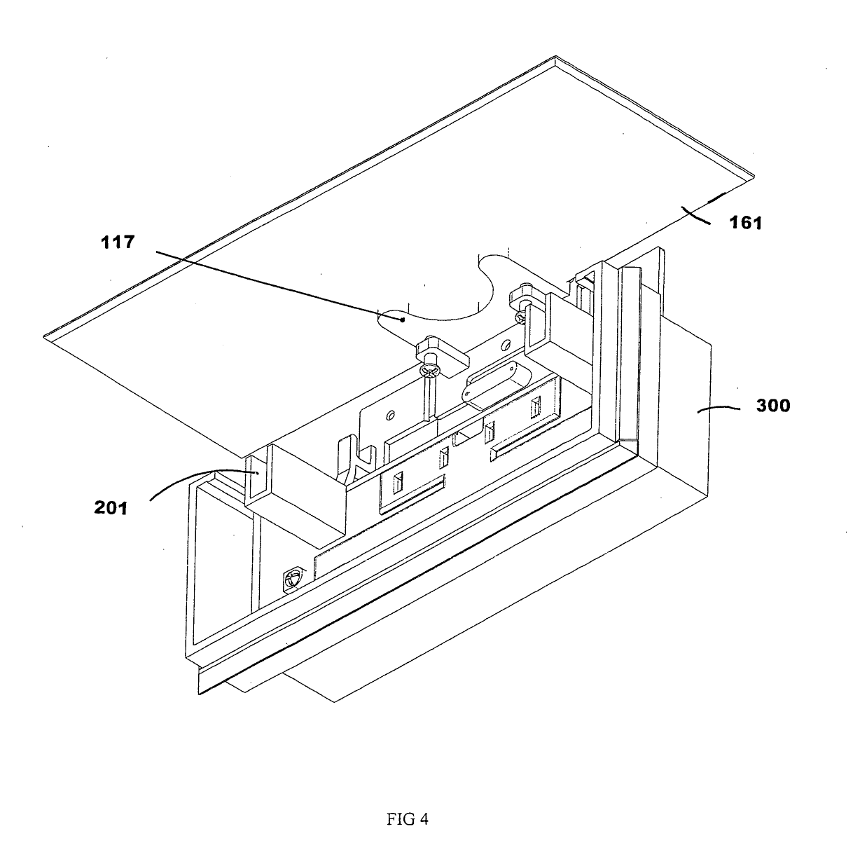

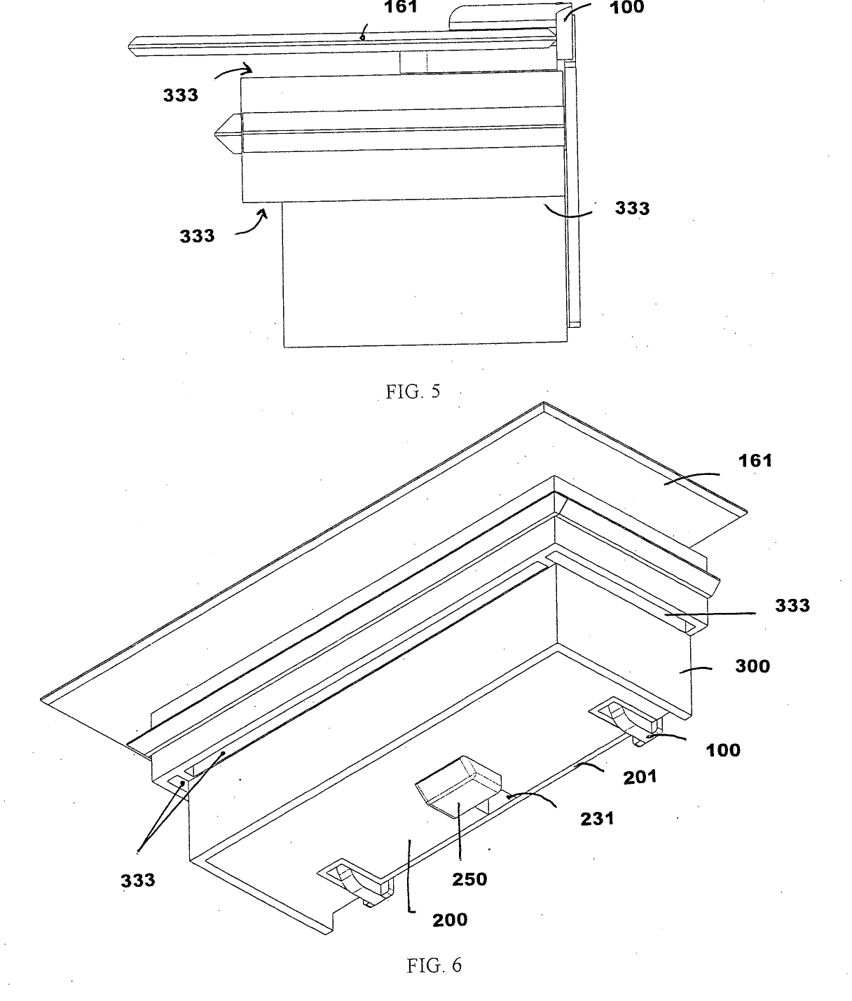

FIG. 3A illustrates a side view of the wall mounting foldable bracket 100, which is connected to the illuminated interchangeable case 300 as shown in FIG. 4 via the pivoting and locking mechanism 201 shown in FIG. 3B. Referring to FIG. 3B, the locking pin 207 is in the up position. When the illuminated interchangeable case 300 is pushed up and the top portion is pulled forward, the locking pin 207 is released as illustrated in 207A. This action takes the illuminated interchangeable shelf 300 from the up or closed position as shown in FIGS. 5 & 6, to the open or down position in FIG. 4. Down or open position 207B and 208A shows that last resting points of the shaded pin 207 and 208, the pivot point 137 from FIG. 3A locks the pivot pin 208 from FIG. 3B in a closed area limiting its range of motion creating an open illuminated interchangeable case 300 best viewed in FIG. 4. Once this action occurs, there is better access to the power and data transfer station and all of its ports, from this position you can also perform maintenance actions such as changing of the illuminated interchangeable case 300, releasing or tightening the glass 161, or concealing and rearranging the cables inside.

FIG. 3B illustrates an enlarged top view of the power and data transfer station 200 detached from the illuminated interchangeable case 300 and the wall mounting foldable bracket 100. The power and data transfer station 200 is an oversized surge protector with media outlets 225 and auxiliary power ports 228. The power and data transfer station is color-coded 223, and is designed to help users locate a specific device with a specific power data outlet. This can be done using several different ways; such as a colored stamp, raised adhesive dot, adhesive tape, symbol or any other type identification material. The pivoting and locking mechanism 201 is attached to the power and data transfer station 200 and the pivoting and locking mechanism 201 keeps the wall mounting foldable bracket 100 aligned with the power and data transfer station 200 while providing a pivot point pin 208 and a locking pin 207 to assist in the overall function of the present invention. Screw holes 206 are aligned on the outer edges of the power and data transfer station 200 thereby allowing illuminated interchangeable case 300 to easily mount to the power and data transfer station 200. The screw holes 206 can be various thread pitches, shapes and sizes. The surge protection outlets 219 protect the electronic devices from surges. If the voltage from the surge protection outlets 219 rise above the accepted level, a surge protector would divert the extra electricity to the outlet's grounding wire 273, as shown in FIG. 3D. The auxiliary power ports 228 run off the surge protector and is designed to deliver a different amount of power that could be less or greater than the surge protected ports. The media outlets 225, run parallel or in a convenient location within the same area of the power outlets 219. The medial outlets 225 can be powered or unpowered depending on its data transfer roll and its configuration. The wire cutout 231 shown in FIG. 3C, allows the space to be used for extra cabling that need to pass through the power and data transfer station 200 to an external connection.

FIG. 3C illustrates an enlarged bottom view of the power and data transfer station 200 attached to the pivoting and locking mechanism 201 and detached from the illuminated interchangeable case 300 and the wall mounting foldable bracket 100. The connection point 250 is a direct link for the power cable 270, with a positive lead 271, a negative lead 275 and a grounding wire 273 which are all fitted with a plug or are capped off inside a wall mounted J-box. The data transfer wire 276, is comprised of any type of wire that is capable of transferring data between electronic devices. The auxiliary connection points 204, are points on the bottom of the data and power transfer station 200 that can be screw holes 206 as shown in FIG. 3B.

FIG. 3D illustrates an enlarged section view of the illuminated interchangeable case 300 with the LED housing 331 and power and data transfer station 200 detached from the case. The LED housing 331 is comprised of one or more LED's 334 and can be made out of a variety of materials. The LED housing 331 can be made into the existing illuminated interchangeable case 300 or attached by clamps, bonded, snap in brackets, screws or other suitable attachment devices using designated holes 332. Once LED housing 331 is attached, the power cable 337 is connected to auxiliary power ports 228. The LED's 334 can be fitted with an electronic mechanism to control or alter the functionality of the LED's 334 such as the changing of colors, brightness, on and off relays, and other automated features.

FIG. 4 illustrates an enlarged right prospective view of the present invention in its open position. The illuminated interchangeable case 300 is attached to the pivoting and locking mechanism 201. The bottom shelf holding bracket 117 holds glass shelf 161 in place.

FIG. 5 illustrates a side view of the present invention in its closed position showing the glass shelf 161 and wall mounting foldable bracket 100. Illuminated areas 333 are openings or spaces that have been cutout or designed for the maximum release of light.

FIG. 6 illustrates a right upwards view of the present invention in its closed position showing glass shelf 161 on top of the illuminated interchangeable case 300 which is attached to the wall mounting foldable bracket 100 and the pivoting and locking mechanism 201. The power and data transfer station 200 is also connected to the wall mounting foldable bracket 100 and the pivoting and locking mechanism 201. The wire cutout 231, connection point 250, and illuminated areas 333 are also depicted.

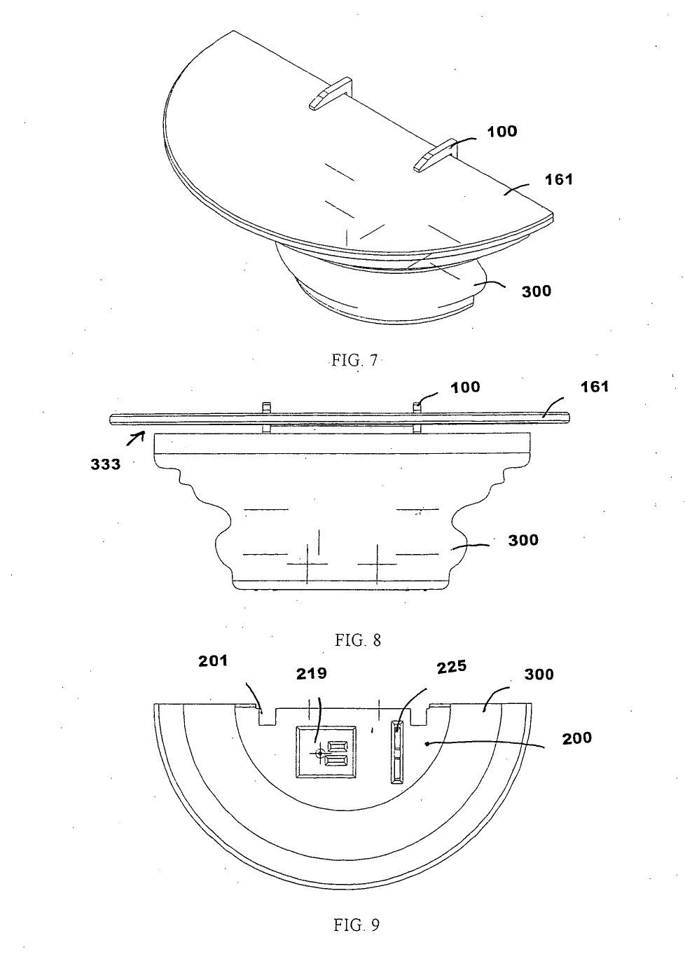

FIG. 7 illustrates a perspective view of the present invention in its closed position with a glass shelf 161 and illuminated interchangeable case 300 in half-moon shape and mounted with wall mounting foldable bracket 100.

FIG. 8 illustrates a frontal view of the present invention in its closed position with a glass shelf 161 and illuminated interchangeable case 300 in half-moon shape and mounted with wall mounting foldable bracket 100 wherein illuminated space 333 is created.

FIG. 9 illustrates a top cutaway view of the present invention in its closed position. The pivoting and locking mechanism 201 is attached to power and data transfer system 200 and illuminated interchangeable case 300. Media outlet 225 and power outlet 219 are depicted.

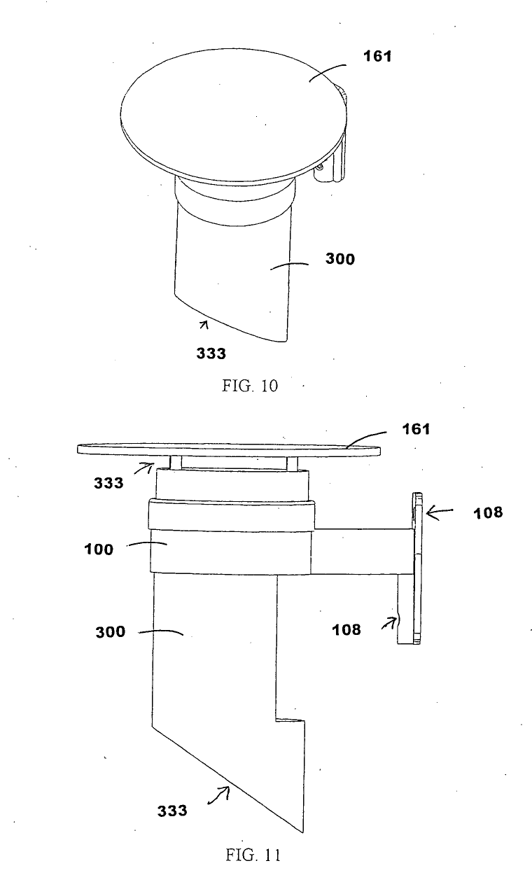

FIG. 10 illustrates a right perspective view of the present invention in a torch shape showing glass shelf 161, illuminated interchangeable case 300 and illuminated space 333.

FIG. 11 illustrates a side view of the present invention in a torch shape showing glass shelf 161, illuminated interchangeable case 300 and illuminated space 333. Wall mounting foldable bracket 100 is mounted to a wall using mounting holes 108.

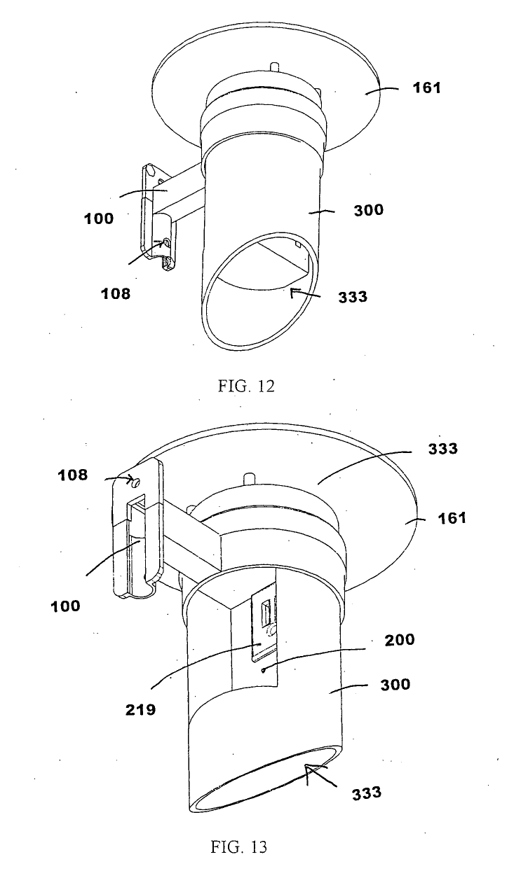

FIG. 12 illustrates a left and upward perspective view of the present invention in a torch shape showing glass shelf 161, illuminated interchangeable case 300 and illuminated space 333. Wall mounting foldable bracket 100 is mounted to a wall using mounting holes 108.

FIG. 13 illustrates a rear upward perspective view of the present invention in a torch shape showing glass shelf 161, illuminated interchangeable case 300 and illuminated spaces 333. Wall mounting foldable bracket 100 is mounted to a wall using mounting holes 108. The surge protection outlet 219 is located on the power and data transfer station 200 located inside the illuminated interchangeable case 300.

The foregoing description of several embodiments of the invention has been presented for purposes of illustration. It is not intended to be exhaustive or to limit the invention to the precise forms disclosed, and obviously many modifications and variations are possible in light of the above teaching. It is intended that the scope of the invention be defined by the claims appended hereto.

What is claimed is:

1. A media display and data transfer system, comprising:
a glass shelf;
a power and data transfer system;
a wall mounting foldable bracket;
a pivoting and locking mechanism;
an illuminated interchangeable display case; and
a LED housing unit.

2. The media display and data transfer system of claim 1 wherein said wall mounting foldable bracket is mounted to a wall through a plurality of mounting holes using screws or other suitable means of mounting and is leveled using a leveling device.

3. The media display and data transfer system of claim 1 wherein said wall mounting foldable bracket holds is comprised of an upper shelf holding bracket, a lower shelf holding bracket wherein upper shelf and lower shelf holding bracket hold said glass shelf in place and wherein said pivoting and locking mechanism and adjustable screws adjust said glass shelf up or down using said pivoting and locking mechanism and said adjustable screws.

4. The media display and data transfer system of claim 3 wherein a space to allow a solid chemical structure or other suitable material to prevent premature wear on the glass shelf is present between said glass shelf and each said upper and lower shelf holding bracket.

5. The media display and data transfer system of claim 1 wherein said power and data transfer system is comprised of:
a surge protector;
a plurality of media outlets;
a plurality of auxiliary power ports;
a plurality of wire cutouts;
a power cable; and
a data transfer wire.

6. The media display and data transfer system of claim 1 wherein said power and data transfer station is attached to said illuminated interchangeable case using screws or other suitable means of attachment.

7. The media display and data transfer system of claim 1 wherein said power and data transfer station is attached to said pivoting and locking mechanism in order to keep the wall mounting foldable bracket aligned with said power and data transfer station.

8. The media display and data transfer system of claim 1 wherein said illuminated interchangeable case contains said LED housing unit.

9. The media display and data transfer system of claim 8 wherein said LED housing unit contains LED's fitted with an electronic mechanism to alter the functionality of said LED's including color, brightness, on and off relays and other automated features.

10. The media display and data transfer system of claim 1 wherein said power and data transfer station is color-coded to better determine which device is connected with which transfer data outlet.

11. A method for displaying media and transferring data using a media display and data transfer system comprising:
a glass shelf;
a power and data transfer system;
a wall mounting foldable bracket;
a pivoting and locking mechanism;
an illuminated interchangeable display case; and
a LED housing unit

12. The media display and data transfer system of claim 11 wherein said wall mounting foldable bracket is mounted to a wall through a plurality of mounting holes using screws or other suitable means of mounting and is leveled using a leveling device.

13. The media display and data transfer system of claim 11 wherein said wall mounting foldable bracket holds is comprised of an upper shelf holding bracket, a lower shelf holding bracket wherein upper shelf and lower shelf holding bracket hold said glass shelf in place and wherein said pivoting and locking mechanism and adjustable screws adjust said glass shelf up or down using said pivoting and locking mechanism and said adjustable screws.

14. The media display and data transfer system of claim 13 wherein a space to allow a solid chemical structure or other suitable material to prevent premature wear on the glass shelf is present between said glass shelf and each said upper and lower shelf holding bracket.

15. The media display and data transfer system of claim 11 wherein said power and data transfer system is comprised of:
a surge protector;
a plurality of media outlets;
a plurality of auxiliary power ports;
a plurality of wire cutouts;
a power cable; and
a data transfer wire.

16. The media display and data transfer system of claim 11 wherein said power and data transfer station is attached to said illuminated interchangeable case using screws or other suitable means of attachment.

17. The media display and data transfer system of claim 11 wherein said power and data transfer station is attached to said pivoting and locking mechanism in order to keep the wall mounting foldable bracket aligned with said power and data transfer station.

18. The media display and data transfer system of claim 11 wherein said illuminated interchangeable case contains said LED housing unit.

19. The media display and data transfer system of claim 18 wherein said LED housing unit contains LED's fitted with an electronic mechanism to alter the functionality of said LED's including color, brightness, on and off relays and other automated features.

20. The media display and data transfer system of claim 1 wherein said power and data transfer station is color-coded to determine which device is connected with which transfer data outlet.
